(19) United States
(12) Patent Application Publication
(10) Pub. No.: US 2025/0384826 A1
(43) Pub. Date: Dec. 18, 2025

(54) DISPLAY DEVICE, LIGHT-EMITTING MODULE THEREOF AND DRIVING METHOD THEREOF

(71) Applicant: Lextar Electronics Corporation, Hsinchu City (TW)

(72) Inventors: Kai-Hsiang SHIH, Hsinchu City (TW); Zheng-Shuo TUNG, Hsinchu City (TW); Cheng-Yeh TSAI, Hsinchu City (TW); Jung-Chien CHANG, Hsinchu City (TW); Chien-Nan YEH, Hsinchu City (TW)

(21) Appl. No.: 19/236,635

(22) Filed: Jun. 12, 2025

(30) Foreign Application Priority Data
Jun. 13, 2024 (TW) 113121867

(51) Int. Cl. G09G 3/32; H10H 29/49

(52) U.S. Cl. CPC G09G 3/32; H10H 29/49; G09G 2300/0452; G09G 2320/0233; G09G 2320/0242; G09G 2330/021

(57) ABSTRACT

A light-emitting module comprises N×M pixel modules arranged in a two-dimensional array wherein N and M are positive integers greater than or equal to 2. Each of the pixel modules comprises a plurality of pixels and a driving circuit for controlling the plurality of pixels. Each of the pixels comprises a plurality of light-emitting diodes. Each driving circuit is configured to apply a driving current to the light-emitting diodes in the corresponding pixel module. In a time period, a duty cycle of a working period of the driving current is 1/J, and in the working period, the driving current is J times an average driving current, and J is a positive integer equal to or greater than 2.

### Cross Reference to Related Applications

This application claims the benefit of Taiwan application Serial No. 113121867, filed Jun. 13, 2024, the subject matter of which is incorporated herein by reference.

### BACKGROUND

### Field of the Disclosure

The disclosure relates in general to a display device, a light-emitting module thereof and a driving method

### Description of the Related Art

A light-emitting module comprises many pixels arranged in an array. The less the pitch of the pixels is, the less the driving current density for the pixels is, and vice versa. Moreover, different types of light-emitting diodes have different characteristics. For example, for red light-emitting diodes, the greater the driving current is, the higher the luminous efficiency is. However, for green/blue light-emitting diodes, the greater the driving current is, the worse the luminous efficiency is. Therefore, how to obtain excellent luminous efficiency while considering many characteristics of light-emitting diodes is one of the directions pursed by industry players in this technical field.

### SUMMARY

The present disclosure relates to a display device, a light-emitting module thereof and a driving method thereof, which may improve the aforementioned conventional problems.

According to an embodiment of the present disclosure, a light-emitting module is provided. The light-emitting module comprises N×M pixel modules in a two-dimensional array wherein N and M are positive integers greater than or equal to 2. Each of the pixels comprises a plurality of light-emitting diodes and a driving circuit for controlling the plurality of pixels. The driving circuit is configured to apply a driving current to the light-emitting diodes in the pixel module. In a time period, a duty cycle of a working interval of the driving current is 1/J, and in the working interval, the driving current is J times an average driving current, and J is a positive integer equal to or greater than 2.

According to another embodiment of the present disclosure, a display device is provided. The display device comprises a light-emitting module and a timing controller. The light-emitting module comprises N×M pixel modules in a two-dimensional array wherein N and M are positive integers greater than or equal to 2. Each of the pixels comprises a plurality of light-emitting diodes and a driving circuit for controlling the plurality of pixels. The driving circuit is configured to apply a driving current to the light-emitting diodes in the pixel module. The timing controller is configured to generate a timing signal and a data signal to drive one of the pixel modules. In a time period, a duty cycle of a working interval of each driving current is 1/J, and in the working interval, the driving current is J times an average driving current, and J is a positive integer equal to or greater than 2.

According to another embodiment of the present disclosure, a driving method for a display device is provided. The driving method comprises the following steps: generating a timing signal and a data signal to a driven one of the N×M pixel modules in a two-dimensional array by a timing controller, wherein each of the pixel modules comprises a plurality of pixels and a driving circuit for controlling the plurality of pixels, each of the pixels comprises a plurality of light-emitting diodes, the driving circuit is configured to apply a driving current to the light-emitting diodes in the pixel module, and N and M are positive integers greater than or equal to 2; and applying a driving current to the light-emitting diodes in the corresponding pixel module by the driven one of the driving circuit, wherein in a time period, a duty cycle of a working interval of each driving current is 1/J, and in the working interval, the driving current is J times an average driving current, and J is a positive integer equal to or greater than 2.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIGS. 1A and 1B illustrate functional block diagrams of a display device according to an embodiment of the present disclosure;

FIG. 2 illustrates a schematic diagram of a pixel module P_{n×m} in FIG. 1A;

FIG. 3 illustrates a relationship diagram between a driving current I_{D} and a driving time in FIG. 2;

FIG. 4 illustrates a cross-sectional view of a pixel in a pixel module P_{n×m} according to an embodiment of the present disclosure; and

FIG. 5 illustrates a schematic diagram of a pixel module P_{n×m} according to other embodiments of the present disclosure.

### DETAILED DESCRIPTION OF THE INVENTION

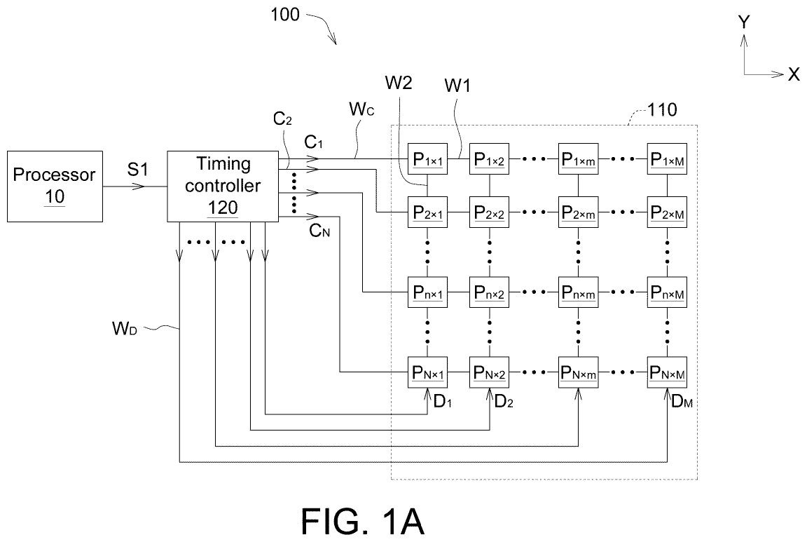

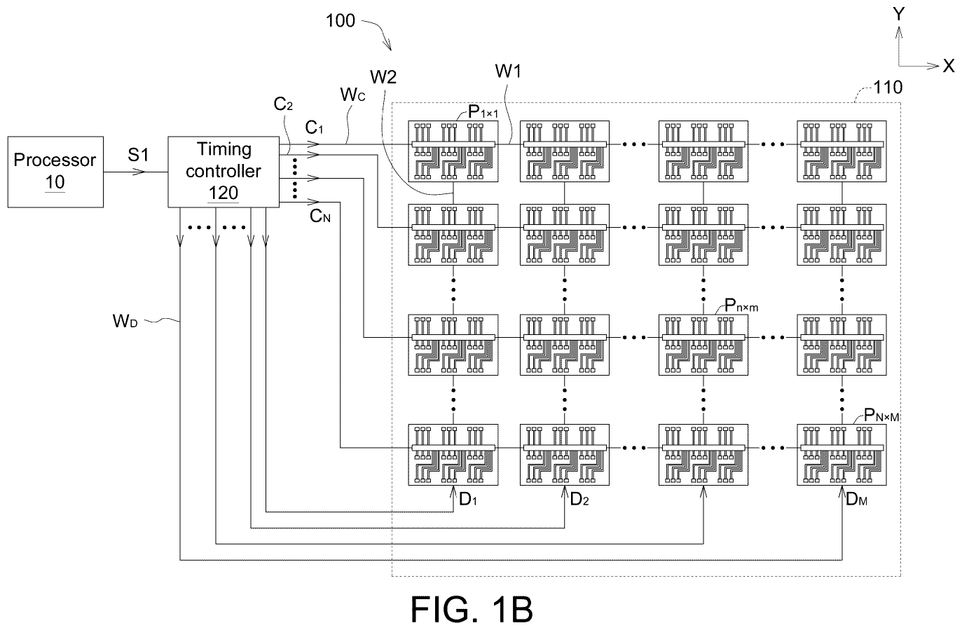

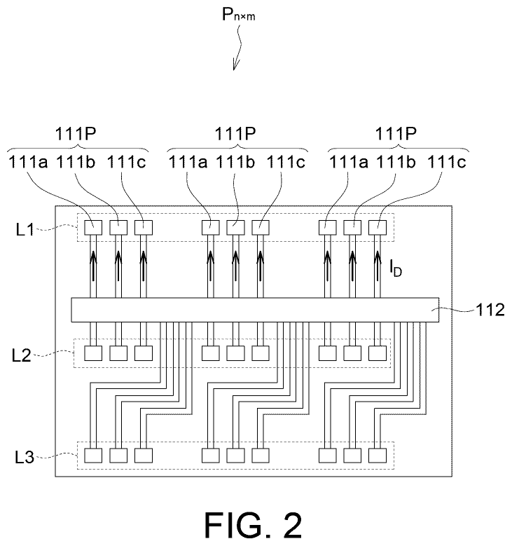

Referring to FIGS. 1A to 3. FIGS. 1A and 1B illustrate functional block diagrams of a display device 100 according to an embodiment of the present disclosure, FIG. 2 illustrates a schematic diagram of a pixel module P_{n×m} in FIG. 1A, and FIG. 3 illustrates a relationship diagram between a driving current I_{D} and time in FIG. 2.

As illustrated in FIGS. 1A and 1B, the display device 100 comprises a light emitting module 110 and a timing controller (T-CON) 120. The light-emitting module 110 comprises N×M pixel modules P_{n×m} which are arranged in a two-dimensional array, wherein N and M are positive integers greater than or equal to 2, n is a positive integer ranging between 1 and N, and m is a positive integer ranging between 1 and M. Each pixel module P_{n×m} comprises a plurality of pixels. In some embodiments, each pixel comprises three sub-pixels that may emit different colors of light, such as red light, green light and blue light respectively. In one embodiment, the sub-pixel comprises a light-emitting diode. In some embodiments, as illustrated in FIG. 2, a pixel module P_{n×m} comprises nine pixels 111P and a driving circuit 112, wherein each pixel 111P may comprise three light-emitting diodes 111a, 111b and 111c, and are electrically connected to the driving circuit 112. In some embodiments, the pixel 111P may comprise four or more sub-pixels, for example, each pixel 111P may comprise four or more light-emitting diodes. For example, the pixel 111P comprises red, green, blue, and cyan sub-pixels emitting four different colors of red, green, blue and cyan, or the pixel 111P comprises red, green, blue and yellow sub-pixels emitting four different colors of red, green, blue and yellow, or the pixel 111P comprises red, green, blue and white sub-pixels emitting four different colors of red, green, blue and white. However, this is not intended to limit the embodiments of the present disclosure.

In some embodiments, the red sub-pixel may be realized by, for example, a red light-emitting diode, a UV light-emitting diode exciting a red wavelength conversion material or a blue light-emitting diode exciting a red wavelength conversion material, the green sub-pixel may be realized by, for example, a green light-emitting diode, a UV light-emitting diode exciting a green wavelength conversion material or a blue light- emitting diode exciting a green wavelength conversion material, the blue sub-pixel may be realized by, for example, a blue light-emitting diode, or a UV light-emitting diode exciting a blue wavelength conversion material, the cyan sub-pixel may be realized by, for example, a UV light-emitting diode exciting a blue-green wavelength conversion material or a blue light-emitting diode exciting a blue-green wavelength conversion material, and the yellow sub-pixel may be realized by, for example, a UV light-emitting diode exciting a yellow wavelength conversion material or a blue light-emitting diode exciting a yellow wavelength conversion material.

As illustrated in FIGS. 1 and 2, these light-emitting diodes 111a, 111b, and 111c constitute a plurality of the pixels 111P in the corresponding pixel module P_{n×m}, and are controlled by the driving circuit 112, and each driving circuit 112 is configured to apply the driving current I_{D} to the light-emitting diodes 111a, 111b, and 111c in the corresponding pixel module P_{n×m}. The timing controller 120 is configured to generate N timing signals C₁ to C_{N} and M data signals D₁ to D_{M} to drive one of the pixel modules P_{n×m}. As illustrated in FIG. 3, in a time period T, a duty cycle of a working interval (for example, the working interval is T/J) of each driving current I_{D} is 1/J, and in one working interval, the driving current I_{D} is J times an average driving current Iₐᵥ (i.e., Iₐᵥ×J). As a result, the driving current I_{D} of the light-emitting diode that is driven is increased to J times, and it may improve the luminous efficiency of the light-emitting diodes (for example, red light-emitting diodes).

Moreover, J is a positive integer equal to or greater than 2, for example. The larger the value of J is, the higher the driving current I_{D} is. Since the duty cycle of the embodiment of the present disclosure is less than 1 (for example, 1/J), even if the driving current I_{D} is increased to J times the average driving current Iₐᵥ in the working interval, the average driving current is still the same as the average driving current Iₐᵥ in the same period T, and no additional power consumption is caused by the increase in the driving current I_{D}.

In a comparative embodiment, the light-emitting module 110 comprises a plurality of pixel modules P_{n×m}, and each pixel module P_{n×m} comprises one driving circuit 112 and one pixel 111P. The current used by the drive circuit 112 of each pixel module P_{n×m} to drive the pixel 111P is the aforementioned “average driving current Iₐᵥ” (the average driving current Iₐᵥ is exemplarily drawn as a dotted line in FIG. 3). As illustrated in FIG. 3, the duty cycle of the average driving current Iₐᵥ in the comparative embodiment is 100%, and the average driving current Iₐᵥ is smaller than the driving current ID.

As illustrated in FIG. 2, three light-emitting diodes 111a, 111b and 111c form one pixel 111P in each pixel module P_{n×m}, and the three light-emitting diodes 111a, 111b and 111c emit red light, green light and blue light respectively. For further example, at least one of the pixels 111P each comprises three light-emitting diodes 111a, 111b and 111c, such as a red light-emitting diode, a green light-emitting diode and a blue light-emitting diode respectively, but this is not intended to limit the embodiment of the present disclosure.

In one embodiment, at least one of the light-emitting diodes 111a, 111b and 111c is, for example, a sub-millimeter light-emitting diode (Mini LED) or a micro light-emitting diode (Micro LED). For example, at least one of the pixels 111P each comprises a red mini LED, a green mini LED and/or a blue mini LED. Alternatively, at least one of the pixels 111P comprises a red micro LED, a green micro LED and/or a blue micro LED. In some embodiments, a micro LED has a grown substrate, and the size of the mini LED ranges from 100 μm to 200 μm. In some embodiments, a micro LED has no grown substrate, and the size of the micro LED less than 100 μm.

As illustrated in FIGS. 1A and 1B, N×M pixel modules P_{n×m} are arranged in M rows along a X-axis and in N columns along a Y-axis. Adjacent two of the driving circuits 112 of the pixel modules P_{n×m} arranged along the X-axis are electrically connected, for example, connected in series by a first signal line W1, and adjacent two of the driving circuits 112 of the pixel modules P_{n×m} arranged along the Y-axis are electrically connected, for example, connected in series by a second signal line W2.

As illustrated in FIG. 2, in one pixel module P_{n×m}, these pixels 111P may be arranged in an G×K array, wherein G and K are positive integers greater than or equal to 1, and the values of G and K may be the same or different, but the product of G and K (that is, G×K) is equal to or greater than 2. In the embodiment of this disclosure, G and K are, for example, three respectively, with a total of nine pixels. In one pixel module P_{n×m}, G×K pixels 111P are arranged in K rows along the X-axis and in G columns along the Y-axis. In the present embodiment, the total number of the pixels 111P of the light-emitting module 110 is, for example, ((N×G)×(M×K)).

As illustrated in FIGS. 1A and 1B, the display device 100 further comprises a plurality of timing signal lines W_{C} and a plurality of data signal lines W_{D}. The timing signal lines W_{C} connect the timing controller 120 with the light-emitting module 110 and is configured to transmit the timing signals C₁ to C_{N}, while the data signal lines W_{D} connects the timing controller 120 with the light-emitting module 110 and is configured to transmit the data signals D₁ to D_{M}. In the present embodiment, the number of the timing signal lines W_{C} is, for example, N, and the number of data signal lines W_{D} is, for example, M. One row of the pixel modules P_{n×m} arranged along the X-axis is connected to the timing controller 120 through one timing signal line W_{C}, and one column of the pixel module P_{n×m} arranged along the Y-axis is connected to the timing controller 120 through one data signal line W_{D}. Furthermore, M pixel modules P_{1×1} to P_{1×M} in a first row receive the timing signal C₁ from the timing signal line W_{C}, and M pixel modules P_{2×1} to P_{2×M} in a second row receive the timing signal C₂ from the timing signal line W_{C}, and so on, and it will not be described again. Furthermore, the N pixel modules P_{1×1} to P_{N×1} in a first column receive the data signal D₁ from the data signal line W_{D}, and the N pixel modules P_{1×2} to P_{N×2} in a second column receive the data signal D₂ from the data signal line W_{D}, and so on, and it will not be described again.

In the aforementioned comparative embodiment, for the light-emitting module 110 including ((N×G)×(M×K)) pixels 111P, the light-emitting module 110 needs (N×G) timing signal lines W_{C} and (M×K) data signal lines W_{D}. Thus, when the resolution of a light-emitting diode display becomes higher, there will be more pixels per unit area, and the number of the timing signal lines and the data signal lines will also increase. As a result, the density of timing signal lines W_{C} and data signal lines W_{D} per unit area in the circuit board will also become higher and higher, and accordingly it will increase the complexity of circuit fabrication. On the other hand, in the present embodiment, for the light-emitting module 110 including ((N×G)×(M×K)) pixels 111P, due to the multiple pixels 111P being disposed in one pixel module P_{n×m}, for example, one pixel module in FIG. 1B and FIG. 2 comprises nine pixels, the number of timing signal lines W_{C} and data signal lines W_{D} may be reduced and the circuits may be simplified. For (G×K) pixels 111P disposed on one pixel module P_{n×m}, compared with the comparative embodiment, the light-emitting module 110 of the embodiment of the present disclosure may reduce (N×G−N) timing signal lines W_{C} and may reduce (M×K−M) data signal lines W_{D}. In other words, the greater the number of pixels 111P in single pixel module P_{n×m} (the greater the values of G and/or K), the less the number of the timing signal lines and the data signal lines in the display device.

In the aforementioned comparative embodiment, the light-emitting module 110 comprises a plurality of the pixel modules P_{n×m}, and each pixel module P_{n×m} comprises the driving circuit 112 and the single pixel 111P. In the comparative embodiment, For (G×K) pixels 111P disposed in a G×K array, (G+K) signal lines (K data signal lines arranged along the X-axis and G timing signal lines arranged along the Y-axis) are required to drive the (G×K) pixels 111P. However, in the light-emitting module 110 of the present embodiment, for the G×K pixels 111P (which are disposed in one pixel module P_{n×m}) arranged in a G×K array, only two signal lines (one first signal line W1 extending along the X-axis and one second signal line W2 extending along the Y-axis) are required to drive the (G×K) pixels 111P in one pixel module P_{n×m}.

Moreover, in the aforementioned comparative embodiment, for (G×K) pixels 111P (i.e., (G×K) pixel modules P_{n×m}) arranged in an G×K array, G or K driving circuits 112 are required to drive the G×K pixels 111P. However, in the light-emitting module 110 of the embodiment of the present disclosure, for (G x K) pixels 111P arranged in an G×K array (i.e., one pixel module P_{n×m}), only one driving circuit 112 is required to drive (G×K) pixels 111P. Therefore, for driving G×K pixels 111P in one pixel module P_{n×m}, the light-emitting module 110 of the embodiment of the present disclosure requires less driving circuits than that of the comparative embodiment. For example, the reduced number of the driving circuits is up to (G−1) or (K−1). In an embodiment, the number of the driving circuits 112 of the light emitting module 110 may be equal to the number of pixel modules P_{n×m}, that is, N×M.

In a pixel module P_{n×m} of the present embodiment, these pixels 111P may be divided into J pixel blocks, and the driving circuit 112 may drive J pixel blocks with the driving current Ip in turn (time-sharing driving), that is, each of the J pixel blocks is driven by the driving current I_{D} at different timings.

For example, as illustrated in FIG. 2, these pixels 111P may be divided into three pixel blocks, such as the pixel blocks in the first row L1, the second row L2 and the third row L3. The driving circuit 112 may drive the three pixels 111P in the first row L1, the three pixels 111P in the second row L2, and the three pixels 111P in the third row L3 in turn with the driving current Ip. That is, the pixels in the first row L1, the second row L2 and the third row L3 are driven by the driving current I_{D} at different timings. Compared with the average driving current Iₐᵥ, the driving current I_{D} driving the pixels 111P in each row is J times the average driving current Iₐᵥ (that is, I_{D}=Iₐᵥ×J), and it may improve the luminous efficiency of certain light-emitting diodes (e.g., red light diodes) in each row. Therefore, in the present embodiment, due to the pixels 111P being divided into three pixel blocks, the driving current I_{D} for driving the pixels 111P in each row is three times the average driving current Iₐᵥ (that is, I_{D}=Iₐᵥ×3).

As illustrated in FIGS. 1A and 1B, the processor 10 is, for example, disposed outside the display device 100, such as a host of a computer. In another embodiment, the processor 10 may also be disposed in the display device 100. The processor 10 is electrically connected to the timing controller 120. The processor 10 may send a low-voltage differential signal (LVDS) S1 to the timing controller 120 through a serial peripheral interface bus (SPI), and accordingly the timing controller 120 sends a timing signal C₁ and a data signal D₁. The data signal D₁ is, for example, a command of a current value for driving the pixel 111P with time, and the timing signals C₁ to C_{N} are, for example, configured to position the driven pixel 111P. The data signal D₁ may be stored in a register (not illustrated) of the driving circuit 112.

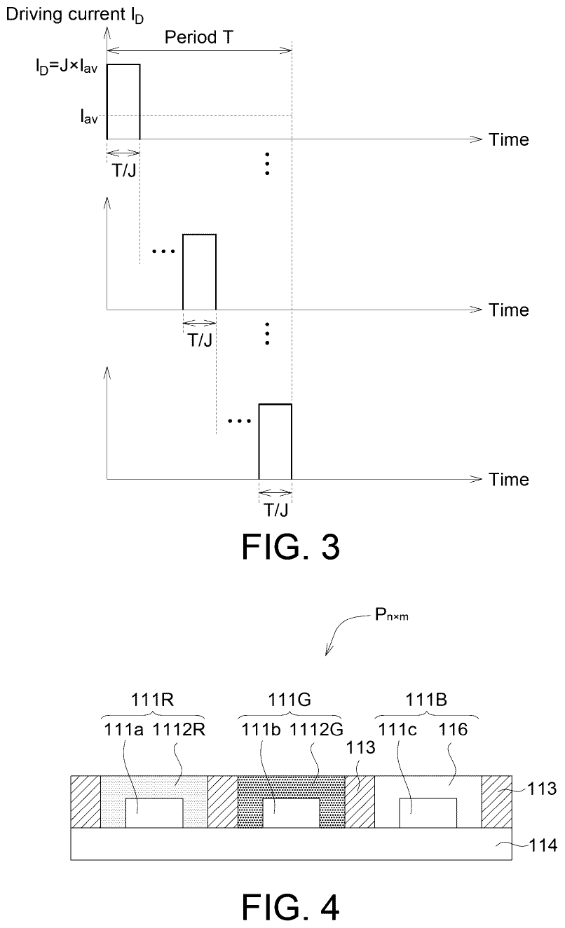

Referring to FIG. 4, FIG. 4 illustrates a cross-sectional view of a pixel in the pixel module P_{n×m} according to an embodiment of the present disclosure. In the pixel module P_{n×m}, pixel 111P comprises red, blue and green sub-pixels. The RGB sub-pixels comprise light-emitting diodes 111a, 111b and 111c electrically connected to the driving circuit 112 (not illustrated), a plurality of light-shielding layers 113 and a circuit substrate 114. The light-emitting diodes 111a, 111b and 111c are disposed and electrically connected to the circuit substrate 114. The light-shielding layer 113 surrounds the light-emitting diodes 111a, 111b and 111c, and adjacent two of the light-emitting diodes 111a, 111b and 111c are separated by the light-shielding layer 113. The light-shielding layer 113 may be, for example, a black matrix.

As illustrated in FIG. 4, the light-emitting diodes 111a, 111b and 111c may be blue light-emitting diodes. The red sub-pixel 111R comprises a light-emitting diode 111a that emits blue light and a red wavelength conversion layer 1112R. The green sub-pixel 111G comprises a light-emitting diode 111b that emits blue light and a green wavelength conversion layer 1112G. The blue sub-pixel 111B comprises a light-emitting diode 111c that emits blue light and a light-transmitting layer 116. The red wavelength conversion layer 1112R comprises, for example, red quantum dots or red phosphors. The red wavelength conversion layer 1112R covers the light-emitting diode 111a and is configured to convert the blue light emitted by the light-emitting diode 111a into red light. The green wavelength conversion layer 1112G comprises, for example, green quantum dots or green phosphors. The green wavelength conversion layer 1112G covers the light-emitting diode 111b and is configured to convert the blue light emitted by the light-emitting diode 111b into green light. The light-transmitting layer 116, for example, does not contain any wavelength converting substances. The light-transmitting layer 116 covers the light-emitting diode 111c, and the blue light emitted by the light-emitting diode 111c may travel through the light-transmitting layer 116 and maintain the blue light.

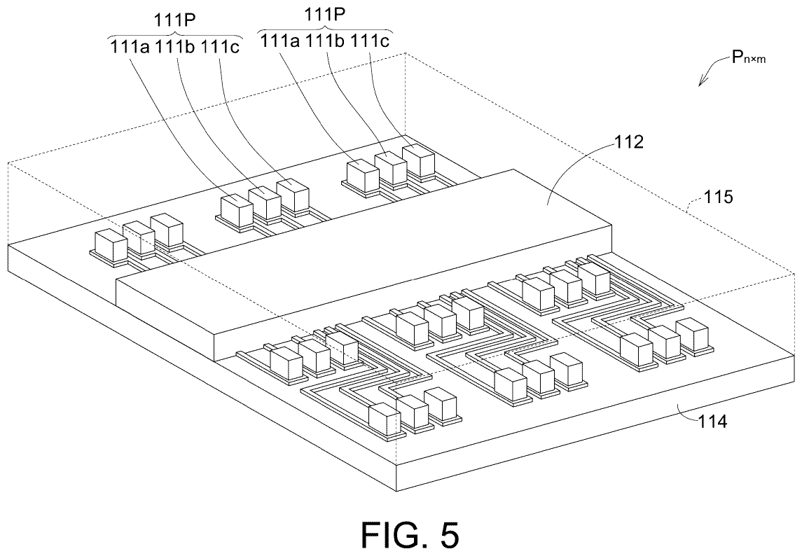

Referring to FIG. 5, FIG. 5 illustrates a schematic diagram of a pixel module P_{n×m} according to other embodiments of the present disclosure. Each pixel module P_{n×m} comprises a plurality of the light-emitting diodes 111a, 111b 111c, the driving circuit 112, the circuit substrate 114 and a package body 115. The light-emitting diodes 111a, 111b and 111c are disposed and electrically connected to the electrical substrate 114. The light-emitting diodes 111a, 111b and 111c are red light-emitting diodes, green light-emitting diodes and blue light-emitting diodes respectively to form a plurality of the pixels 111P and are controlled by the driving circuit 112. The package body 115 is configured to package the light-emitting diodes 111a, 111b 111c and the driving circuit 112. In FIG. 5, the pixel module comprises nine groups of the light-emitting diodes 111a, 111b and 111c (one light-emitting diode 111a, one light-emitting diode 111b and one light-emitting diode 111c may constitute one group), and the nine groups constitute nine pixels. In some embodiments, the package body 115 comprises a light-transmissive resin.

Moreover, although not depicted in the figures, each pixel module P_{n×m} further comprises a plurality of electrical pads, such as grounding pads, timing pads, data pads and power pads. The signals from the timing controller 120 are transmitted to the pixel module P_{n×m} through these electrical pads. The timing pad may be electrically connected to the timing signal line W_{C}, the data pad may be electrically connected to the data signal line W_{D}, and the power pad is electrically connected to the driving circuit 112. An external power supply (not illustrated) may be supplied to the driving circuit 112 through the power pad. Compared with the aforementioned comparative embodiment, the pixel module P_{n×m} in the embodiment of the present disclosure may be a package containing a plurality of the light-emitting diodes and the driving circuit, and its bottom surface provides a sufficient bottom area so that the area of the electrical pads formed on the bottom surface may become larger, and a distance between the two electrical pads may be further apart.

In summary, embodiments of the present disclosure provide a display device, a light-emitting module thereof and a driving method thereof. The light-emitting module comprises a plurality of pixel modules, each pixel module comprises J pixel blocks, wherein each of the J pixel areas comprises at least one pixel, and each pixel comprises three light-emitting diodes. For one pixel module, in a time period, the duty cycle of the driving current is 1/J and the current value is J times the average driving current, and accordingly it may improve the luminous efficiency of the light-emitting diodes (for example, red light diodes). In the experimental example where the pixel pitch is 0.36 millimeter (mm) and J is equal to 3, the driving current for the red light diode is 33 microamperes (μA) and the brightness is 17.2 (Cd/m²), the driving current for the green light diode is 10.5 microamperes and the brightness is 83.8 (Cd/m²), and the driving current for the blue light diode is 12 microamperes and the brightness is 11.3 (Cd/m²). When driving, the power consumption of the light-emitting module 110 is reduced by 3% to 5% (compared to conventional light-emitting modules).

While the disclosure has been described by way of example and in terms of the preferred embodiment(s), it is to be understood that the disclosure is not limited thereto. Based on the technical features embodiments of the present disclosure, a person ordinarily skilled in the art will be able to make various modifications and similar arrangements and procedures without breaching the spirit and scope of protection of the disclosure. Therefore, the scope of protection of the present disclosure should be accorded with what is defined in the appended claims.

What is claimed is:

1. A light-emitting module, comprising:
N×M pixel modules arranged in a two-dimensional array wherein N and M are positive integers greater than or equal to 2;
wherein each of the pixel modules comprises a plurality of pixels and a driving circuit for controlling the plurality of pixels, each of the pixels comprises a plurality of light-emitting diodes, and the driving circuit is configured to apply a driving current to the light-emitting diodes in the pixel module, and
wherein in a time period, a duty cycle of a working interval of the driving current is 1/J, and in the working interval, the driving current is J times an average driving current, and J is a positive integer equal to or greater than 2.

2. The light-emitting module according to claim 1, wherein each of the pixel module further comprises:
a package body packaging the light-emitting diodes of the pixels and the driving circuit.

3. The light-emitting module according to claim 1, wherein each of the pixels comprises at least three light-emitting diodes.

4. The light-emitting module according to claim 1, wherein the pixels in each of the pixel modules are divided into J pixel blocks.

5. The light-emitting module according to claim 4, wherein the J pixel blocks are driven by the driving current at different timings.

6. The light-emitting module according to claim 5, wherein the driving current for driving the pixels in each of the pixel blocks is J times the average driving current.

7. A display device, comprising:
a light-emitting module, comprising:
N×M pixel modules arranged in a two-dimensional array wherein N and M are positive integers greater than or equal to 2, wherein each of the pixel modules comprises a plurality of pixels and a driving circuit for controlling the plurality of pixels, each of the pixels comprises a plurality of light-emitting diodes, and the driving circuit is configured to apply a driving current to the light-emitting diodes in the pixel module; and
a timing controller configured to generate a timing signal and a data signal to drive one of the pixel modules;
wherein in a time period, a duty cycle of a working interval of the driving current is 1/J, and in the working interval, the driving current is J times an average driving current, and J is a positive integer equal to or greater than 2.

8. The display device according to claim 7, wherein each pixel module further comprises:
a package body packaging the light-emitting diodes of the pixels and the driving circuit.

9. The display device according to claim 7, wherein each of the pixels comprises at least three light-emitting diodes.

10. The display device according to claim 7, wherein the pixels in the pixel module are divided into J pixel blocks.

11. The display device according to claim 10, wherein the J pixel blocks are driven by the driving current at different timings.

12. The display device according to claim 11, wherein the driving current for driving the pixels in each of the pixel block is J times the average driving current.

13. The display device according to claim 7, further comprising:
a plurality of timing signal lines connecting the timing controller with the light-emitting module, the timing signal lines configured to transmit the timing signals to the pixel modules; and
a plurality of data signal lines connecting the timing controller with the light-emitting module, the data signal lines configured to transmit the data signals to the pixel modules.

14. The display device according to claim 8, wherein the pixel module comprises a plurality of pads on a bottom surface of the package body, and the timing signal and the data signal from the timing controller are transmitted to the pixel module through the pads.

15. A driving method for a display device, comprising:
generating a timing signal and a data signal to a driven one of the N×M pixel modules in a two-dimensional array by a timing controller, wherein each of the pixel modules comprises a plurality of pixels and a driving circuit for controlling the plurality of pixels, each of the pixels comprises a plurality of light-emitting diodes, the driving circuit is configured to apply a driving current to the light-emitting diodes in the pixel module, and N and M are positive integers greater than or equal to 2; and
applying a driving current to the light-emitting diodes in the corresponding pixel module by the driven one of the driving circuit, wherein in a time period, a duty cycle of a working interval of the driving current is 1/J, and in the working interval, the driving current is J times an average driving current, and J is a positive integer equal to or greater than 2.

16. The driving method for the display device according to claim 15, wherein the light-emitting diodes are sub-millimeter light-emitting diodes or micro-light emitting diodes.

17. The driving method for the display device according to claim 15, wherein the pixels in the pixel module are divided into J pixel blocks, and the J pixel blocks are driven by the driving current at different timings.

18. The driving method for the display device according to claim 17, wherein the driving current for driving the pixels in each of the pixel block is J times the average driving current.
